(19) United States
(12) Patent Application Publication
(10) Pub. No.: US 2026/0215221 A1
(43) Pub. Date: Jul. 23, 2026

(54) METHODS AND APPARATUS FOR FACILITATING MANUFACTURE OF AN INTEGRATED CIRCUIT ON A CARRIER

(71) Applicant: Pragmatic Semiconductor Limited, Cambridge (GB)

(72) Inventors: Richard PRICE, Cambridge (GB); Bobur MIRKHAYDAROV, Cambridge (GB); Lee WINCHESTER, Cambridge (GB); Devaraj SHANMUGAM, Cambridge (GB)

(73) Assignee: Pragmatic Semiconductor Limited, Cambridge (GB)

(21) Appl. No.: 19/567,436

(22) Filed: Mar. 16, 2026

Related U.S. Application Data
(63) Continuation of application No. PCT/GB2024/052287, filed on Sep. 3, 2024.

(30) Foreign Application Priority Data
Sep. 15, 2023 (GB) 2314148.4

(51) Int. Cl. H10P 72/70; H10P 50/00; H10P 50/28; H10P 76/40

(52) U.S. Cl. CPC H10P 72/7412; H10P 50/286; H10P 50/73; H10P 72/744; H10P 76/405; H10P 76/4085

(57) ABSTRACT

Methods of, and apparatus for, manufacturing integrated circuits (ICs) are disclosed. The method includes processing a carrier for supporting a plurality ICs during fabrication and for aiding release of the ICs following fabrication. Processing the carrier includes providing a layer of a release material thereon, which is subsequently patterned prior to the deposition of substrate materials upon which ICs are formed.

### RELATED APPLICATIONS

This application is a Continuation of PCT Patent Application No. PCT/GB2024/052287 having International filing date of Sep. 3, 2024, which claims the benefit of priority of United Kingdom Patent Application No. GB2314148.4 filed on Sep. 15, 2023. The contents of the above applications are all incorporated by reference as if fully set forth herein in their entirety.

### FIELD AND BACKGROUND OF THE INVENTION

The present invention relates to methods and apparatus for supporting the manufacture of integrated circuits (ICs). The present invention relates in particular, but is not limited to, providing a carrier for supporting a plurality of integrated circuits during manufacture, and methods and apparatus for manufacturing a plurality of discrete ICs on the carrier.

Typically, during the manufacture of ICs, a wafer consisting of a thin layer of semiconductor material such as crystalline Silicon (c-Si) or Gallium arsenide (GaAs) is provided which serve as a substrate for supporting microelectronics that form the ICs. Such wafers typically have an extreme level of purity and are formed in a single crystal structure.

During the manufacturing process the ICs may be built up on the wafer. For example, devices such as diodes, transistors, capacitors, and resistors, can be built up by forming p-type and n-type regions, at appropriate locations, in the semiconductor substrate using appropriate doping, and by building up one or more layers of insulating and/or conducting material using appropriate fabrication processes. The location of the n-type and p-type regions and the pattern of insulating and/or conducting material in each layer defining the devices, and the interconnectivity between them, is typically defined using appropriate photolithographic processes.

Once built up, each individual IC (known as a ‘die’) is separated from the other ICs on the wafer, which typically involves slicing the ICs apart in a process known as ‘singulation’ or ‘dicing’. Singulation of the ICs is typically performed by dicing the substrate along straight lines (known as scribe lines) between the ICs, typically using a laser or abrasive water jet. During handling of the resulting ‘singulated’ IC, a single die may be picked up using an appropriate pick tool and either placed directly onto a support having corresponding contact pads during the formation of an electronic circuit or, if orientation flipping is required, placed onto another pick tool before placement onto the support having corresponding contact pads.

Whilst fabrication on crystalline semiconductor substrates is widespread, fabrication of ICs may be carried out on other substrate materials including insulating substrates. For example, it is known to use a flexible substrate formed of, for example, a thin, heat-resistant material such as polymers. Where the substrate is flexible, a rigid carrier is typically used to support the substrate during the subsequent manufacture of electronic devices on that substrate to form an IC, for example using manufacturing processes similar to those described above for a crystalline semiconductor wafer.

As with crystalline semiconductor-based ICs, flexible substrate-based ICs, once fabricated, are typically separated (or diced) into individual dies for subsequent removal and integration into an end product. However, separation processes such as dicing, which involve lasers or water jets are time-consuming and can produce contaminant waste material that require removal from the substrate following dicing. Furthermore, the processes may generate significant local heating of the substrate and may produce poor edge quality around each singulated IC, which can adversely affect yield and/or uniformity, especially in the context of flexible substrates. In addition, the scribe line width formed between each of the discrete ICs in a dicing process of this type can be relatively large, which can represent a waste of valuable substrate.

Moreover, simply lifting the individual ICs directly off the carrier (e.g., using a conventional pick tool) risks damaging the substrate and hence the IC.

A variety of different methods for removing individual ICs developed on a flexible substrate from a carrier have been developed to avoid unwanted deformations of the flexible substrate. One such commonplace method used is laser lift-off (LLO). LLO is regularly used in industry due to its large-area compatibility. Nevertheless, LLO methods can pose issues when trying to remove a flexible substrate from a carrier because the laser beam can cause laser illumination induced stress and thermal stress in the substrate and the ICs, which can cause damage to the electrical components of the ICs. The introduction of an additional layer during the fabrication of the ICs that alters the adhesion between the flexible substrate and the carrier has been considered as a possible way of avoiding such laser illumination induce stress and thermal stress. However, the application of such additional layers requires a long immersion time during manufacture, and can reduce the performance of the device.

It is an objective of the present invention to provide methods and apparatus that support IC manufacturing improvements.

### SUMMARY OF THE INVENTION

In an example herein disclosed there is provided a method of processing a carrier for supporting a plurality of integrated circuits, ICs, during fabrication and for aiding release of the ICs following fabrication. The method may comprise providing a carrier for supporting a substrate material during fabrication of the ICs on the substrate material, the carrier having a first surface and a second surface opposite the first surface; forming, on the first surface of the carrier, a layer of release material for receiving the substrate material, and for aiding release of the substrate material following fabrication of the ICs; and patterning the release material formed on the carrier to define a plurality of distinct IC support areas in the release material, each IC support area being arranged to bond to a respective portion of the substrate material for fabrication of a corresponding IC on that portion of substrate material; wherein the layer of release material is configured for allowing at least part of at least one specific wavelength of electromagnetic radiation incident on the release material to act, at an interface between the release material and the substrate material, to reduce a strength of the bond between the release material and the substrate material.

The carrier provided in the method of processing the carrier may be configured for allowing the at least one specific wavelength of electromagnetic radiation, when incident on the second surface of the carrier, to pass through the carrier, and wherein the layer of release material is configured for absorbing part of the at least one specific wavelength of electromagnetic radiation to produce heat in the layer of release material, and for allowing part of the at least one specific wavelength of electromagnetic radiation to pass through the carrier to reach an interface between the release material and the substrate material to reduce the strength of the bond between the release material and the substrate material.

Patterning of the release material in the method of processing the carrier may comprise forming a plurality of regions extending between and/or adjacent to the IC support areas, at least part of each region comprising an absence of release material or a thinner layer of release material. At least one region of the plurality of regions may comprise release material forming at least one test structure support area, each test structure support area being arranged to bond to a respective further portion of the substrate material for fabrication of a corresponding test structure on that portion of the substrate material. At least one region of the plurality of regions may comprise a linear repeating pattern of windows in the release material that extends generally parallel to an edge of at least one IC support area, each window comprising an absence of release material or a thinner layer of release material. At least one region of the plurality of regions may comprise a portion of release material that connects neighbouring IC support areas.

The patterning of the release material in the method of processing the carrier may define at least one feature pattern in at least one edge of at least one of the IC support areas, the at least one feature pattern comprising an absence of release material or a thinner layer of release material.

The patterning of the release material in the method of processing the carrier may form IC support areas that are configured to act as a photomask during subsequent processing to pattern the substrate material.

The patterning of the release material in the method of processing the carrier may comprise applying a photoresist to the release material; applying electromagnetic radiation to the release material through a photomask for selectively exposing the photoresist to the applied electromagnetic radiation; removing photoresist to define a pattern to be etched in the release material; and etching the release material where the photoresist has been removed.

The method of processing the carrier for supporting the plurality of ICs may further comprise forming a template layer on the first surface of the carrier prior to forming the layer of release material; and patterning the template layer to define a plurality of distinct windows, in the template layer, corresponding to the IC support areas wherein, following the formation of the layer of release material, the release material covers the plurality of distinct windows and remaining part of the template layer. The patterning of the release material may also comprise removing the template layer from the first surface to define the plurality of distinct IC support areas in the release material.

The layer of release material may have a thickness of between 20 nm and 300 nm, preferably between 23 nm and 150 nm.

The release material may be formed of one or more metals selected from one or more of groups 4, 5 and 6 of the periodic table. For example, the release material is formed of one more metals, oxides of metals, or alloys of metals, wherein said metals are selected from one or more of: Hafnium (Hf), Vanadium (V), Niobium (Nb), Tantalum (Ta), Titanium (Ti), Tungsten (W), Molybdenum (Mo), Aluminium (Al), Copper (Cu), Gold (Au), Silver (Ag), Iron (Fe), Tin (Sn), Zinc (Zn), Cobalt (Co), Chromium (Cr), Germanium (Ge), Palladium (Pd), Platinum (Pt), Rhodium (Rh), Manganese (Mn), Nickel (Ni), Silicon (Si), or Tellurium (Te).

The carrier used may be formed of glass, polycarbonate or quartz.

In an example herein disclosed there is provided a method of manufacturing at least one IC, the method comprising: providing a carrier processed as previously described; forming a layer of the substrate material on the carrier; patterning the substrate material to form a respective portion of the substrate material on each IC support area; fabricating a respective IC on each portion of the substrate material; irradiating the carrier with the at least one specific wavelength of electromagnetic radiation to reduce the strength of the bond between the release material and the substrate material; and removing at least one portion of the substrate material, on which the at least one IC is fabricated, from the carrier.

The patterning of the substrate material in the method of manufacturing the at least one IC may comprise applying a photoresist to the substrate material; applying electromagnetic radiation to the substrate material through a photomask for selectively exposing the photoresist to the applied electromagnetic radiation; removing photoresist to define a pattern to be etched in the substrate material; and etching the substrate material where the photoresist has been removed.

The substrate material used in the method of manufacturing the at least one IC may be photoimageable, and patterning of the substrate material may comprise applying electromagnetic radiation to the substrate material through a photomask for selectively exposing the substrate material to the applied electromagnetic radiation; and etching the substrate material where it was exposed to the applied electromagnetic radiation.

The electromagnetic radiation applied during patterning in the method of manufacturing the at least one IC may be applied to the substrate through the second surface of the carrier, and the plurality of distinct IC support areas may form the photomask.

The patterning of the substrate material in the method of manufacturing the at least one IC may comprise applying a photoresist to the substrate material; applying electromagnetic radiation to the second surface of the carrier for selectively exposing the photoresist to the applied electromagnetic radiation through the carrier, the layer of release material acting as a photomask; removing photoresist to define a pattern to be etched in the substrate material; and etching the substrate material where the photoresist has been removed.

The patterning of the release material in the method of manufacturing the at least one IC may form a plurality of regions extending between and/or adjacent to the IC support areas, and it may further form at least one test structure in at least one region of the plurality of regions.

Irradiating the second surface of the carrier in the method of manufacturing the at least one IC may comprise irradiating the second surface to induce, through absorption of radiation by the substrate material, photonic ablation at an interface between the release material and the substrate material to reduce the strength of the bond between the release material and the substrate material.

In an example herein disclosed there is provided a structure for supporting a plurality of integrated circuits, ICs, during fabrication and for aiding release of the ICs following fabrication, the structure comprising: a carrier for supporting a substrate material during fabrication of the ICs on the substrate material; and a layer of release material formed, on a surface of the carrier, for receiving the substrate material, and for aiding release of the substrate material following fabrication of the ICs; wherein the release material is patterned on the carrier to define a plurality of distinct IC support areas in the release material, each IC support area being arranged to bond to a respective portion of the substrate material for fabrication of a corresponding IC on that portion of substrate material; and wherein the layer of release material is configured for allowing at least part of at least one specific wavelength of electromagnetic radiation incident on the release material to act, at an interface between the release material and the substrate material, to reduce a strength of the bond between the release material and the substrate material.

In an example herein disclosed there is provided an apparatus for processing a carrier for supporting a plurality of integrated circuits, ICs, during fabrication and for aiding release of the ICs following fabrication, the apparatus comprising: means for providing a carrier for supporting a substrate material during fabrication of the ICs on the substrate material, the carrier having a first surface and a second surface opposite the first surface; means for forming, on the first surface of the carrier, a layer of release material for receiving the substrate material, and for aiding release of the substrate material following fabrication of the ICs; and means for patterning the release material formed on the carrier to define a plurality of distinct IC support areas in the release material, each IC support area being arranged to bond to a respective portion of the substrate material for fabrication of a corresponding IC on that portion of substrate material; wherein the layer of release material is configured for allowing at least part of at least one specific wavelength of electromagnetic radiation incident on the release material to act, at an interface between the release material and the substrate material, to reduce a strength of the bond between the release material and the substrate material.

In an example herein disclosed there is provided an apparatus for manufacturing at least one IC comprising an apparatus for processing a carrier for supporting a plurality of integrated circuits, ICs, during fabrication and for aiding release of the ICs following fabrication as previously described, and a carrier to form a structure as previously described. The apparatus comprises: means for forming a layer of the substrate material on the carrier; means for patterning the substrate material to form a respective portion of the substrate material on each IC support area; for fabricating a respective IC on each portion of the substrate material; means for irradiating the carrier with the at least one specific wavelength of electromagnetic radiation to reduce the strength of the bond between the release material and the substrate material; and means for removing at least one portion of the substrate material, on which the at least one IC is fabricated, from the carrier.

It will be appreciated that any method of processing a carrier and/or method of manufacturing an IC described herein may be performed using any appropriate semiconductor processing apparatus that would be well known to the skilled person in the art.

### BRIEF DESCRIPTION OF THE SEVERAL VIEWS OF THE DRAWINGS

Embodiments of the invention will now be described, by way of example, with reference to the accompanying drawings in which:

FIG. 1 illustrates a carrier for supporting substrates on which integrated circuits are to be formed;

FIGS. 2a-2e show, schematically, the steps of a manufacturing process to manufacture the carrier of FIG. 1 and a plurality of discrete IC substrates on that carrier;

FIG. 3a shows, schematically, a plurality of discrete IC substrates formed on a carrier with patches of carrier exposed therebetween;

FIGS. 3b-3d each show, schematically, a respective plurality of discrete IC substrates formed on a carrier supporting test structure;

FIG. 4 shows, schematically, a plurality of discrete IC substrates formed on a carrier with at least one IC substrate having indentations;

FIGS. 5a-5c show a variety of polygons that represent possible shapes of discrete IC substrates formed on a carrier;

FIG. 6 is a simplified flow chart of a process of manufacturing a plurality of discrete IC substrate areas on a carrier;

FIG. 7 is a simplified flow chart of a process of manufacturing a plurality of discrete IC substrates (and ICs) on a carrier; and

FIG. 8 is a simplified flow chart of a process to release discrete IC substrates from a carrier.

### DESCRIPTION OF SPECIFIC EMBODIMENTS OF THE INVENTION

### Overview

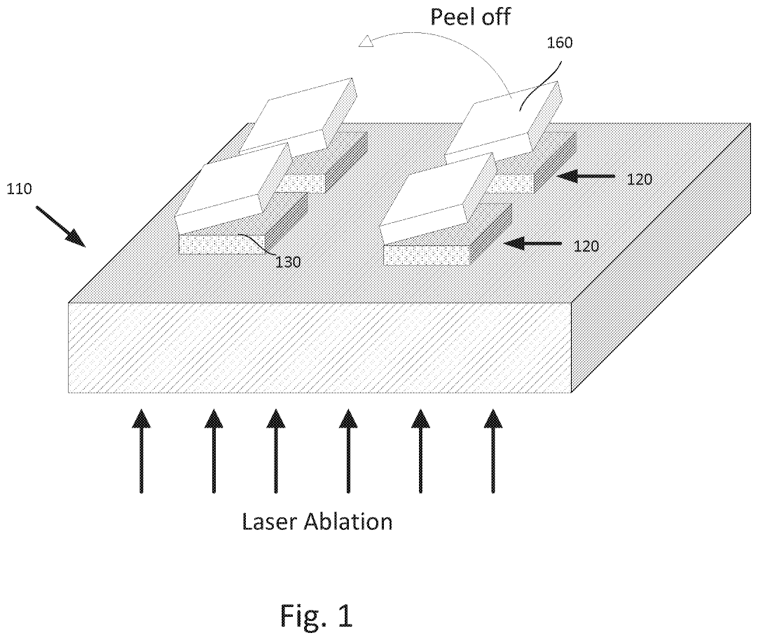

Apparatus for supporting the manufacture of integrated circuits will now be described in overview, by way of example only, with reference to FIG. 1, which illustrates, generally at 110, a carrier for supporting substrates on which integrated circuits (ICs) are to be formed.

The carrier 110 in the illustrated example is a rigid carrier formed from a transparent material such as glass although it will be appreciated that the carrier 110 may be formed of any suitable material, for example, polycarbonate, quartz, silicon, or any other known materials suitable for supporting the substrate.

As seen in FIG. 1, the carrier 110 comprises a patterned layer of material 120 for aiding the later release and removal of ICs formed on the carrier 110. This layer 120 may be referred to generally as a ‘debonding’, ‘release’, or ‘releasable debonding’ layer.

Beneficially, the debonding layer 120 is patterned to provide a plurality of distinct IC support areas 130 (referred to generally as ‘IC areas’in the description), each of which has a size, shape, and position configured for supporting a respective portion of a substrate material 160 during fabrication of a corresponding IC on that portion of substrate material 160. This portion of substrate material 160 will be referred to generally as an IC substrate in the description for clarity.

The debonding layer 120, in the illustrated example, may be formed from one or more of: Hafnium (Hf), Vanadium (V), Niobium (Nb), Tantalum (Ta), Titanium (Ti), Tungsten (W), Molybdenum (Mo), Aluminium (Al), Copper (Cu), Gold (Au), Silver (Ag), Iron (Fe), Tin (Sn), Zinc (Zn), Cobalt (Co), Chromium (Cr), Germanium (Ge), Palladium (Pd), Platinum (Pt), Rhodium (Rh), Manganese (Mn), Nickel (Ni), Silicon (Si), Tellurium (Te), oxides of the foregoing, and alloys of the foregoing. For example, the debonding layer 120 may be formed from one or more metals of: groups 4, 5, and 6 of the IUPAC periodic table, oxides thereof, and alloys thereof. For example, the debonding layer may be formed of one or more of Hafnium (Hf), Vanadium (V), Niobium (Nb), Tantalum (Ta), Chromium (Cr), Molybdenum (Mo), Titanium (Ti), or Tungsten (W), oxides thereof, and alloys thereof. Debonding layers formed from Ti, W, TiW, or Mo have been found to be particularly beneficial for facilitating a controlled release of the substrate material. Nevertheless, as described in more detail later, the debonding layer 120 may be formed from any suitable material (referred to generally as ‘release material’) for facilitating controlled release of the IC substrates (and hence any discrete ICs formed on those IC substrates) from the carrier 110. Moreover, the debonding layer 120 in the illustrated example, may be patterned using photolithography but may be patterned using any other suitable technique.

The debonding layer 120 aids the removal of, whilst minimising damage to, the IC substrates 160, by allowing the strength of the bond between the debonding layer 120 and the substrate material 160 to be reduced to ‘release’ the substrate material. It will be appreciated that after release the substrate may, nevertheless, remain sufficiently adhered to the debonding layer (i.e., the bond strength remains sufficiently high) to facilitate transportation of the ICs in situ on the carrier 110.

Specifically, the release of one or more IC substrates 160 from the carrier 110, in the illustrated example, may be facilitated by means of an optically induced reduction in the bond strength at the interface between the IC substrates 160 and the corresponding IC areas 130 of the debonding layer 120. This optically induced reduction in the bond strength may be achieved, for example, by suitable irradiation of the debonding layer 120 with electromagnetic radiation to ablate a surface of the IC substrates 160 (and/or debonding layer 120) at the interface.

FIG. 1 shows, by way of example only, release of the IC substrates 160 from the carrier 110 by irradiating a reverse side of the carrier (the side of the carrier opposite to the side on which the IC substrates 160 are formed) with, in this example, a laser. In this example, such reverse side irradiation methods are facilitated by using a carrier that is substantially transparent to the wavelengths required to facilitate ‘release’ at the interface between the debonding layer and the substrate. While laser ablation is particularly beneficial (especially in the context of metal based debonding layers, such as a TiW or Mo debonding layer) it will be appreciated that other irradiation sources may be used such as, but not limited to, flashlamps, high-powered LEDs, infrared radiation sources, or other suitable sources of electromagnetic radiation that can cause photonic ablation (e.g., through absorption and/or a similar thermal or other process suitable for reducing the bond strength between the IC substrates 160 and the IC areas 130 of the debonding layer 120 to release the IC substrates 160). Nevertheless, it will be appreciated that front side irradiation may, potentially, be used to release the IC substrates 160 (e.g., where the carrier does not allow transmission of the required wavelength(s) of electromagnetic radiation).

The electromagnetic radiation used to irradiate the reverse side of the carrier 110 propagates through the carrier 110 and partially through the IC areas 130 formed in the debonding layer 120. The debonding layer 120 in turn may absorb some, but not all, of the electromagnetic radiation. The electromagnetic radiation that is transmitted through the debonding layer 120 may, for example, be sufficient to gently heat up the interface between each IC substrate and its corresponding IC area 130 of the debonding layer 120. As the strength of the bond between the IC substrate 160 and the corresponding IC area 130 of the debonding layer 120 is reduced the IC is effectively released.

By absorbing some of the incident electromagnetic radiation, the debonding layer 120 beneficially acts as an ‘ablation’ buffer for the electromagnetic radiation that protects the IC substrates 160 and hence reduces the risk of possible damage to the IC substrates 160.

Once the IC substrates 160 are released, they can be removed from the carrier 110 for use. For example, an IC substrate 160 (and hence the associated IC) may be removed from the carrier by peeling (as illustrated in FIG. 1), which may follow one or more optional processes for assisting with the removal of the IC substrates 160 from the carrier 110.

It can be seen, therefore, that the carrier having a pre-patterned layer of release material (debonding layer 120) formed on it beneficially provides a base upon which to form ICs on corresponding IC substrates that can be subsequently released and removed with relative ease and with minimal risk of damage both to the ICs and to the release layer itself. The carrier with the pre-patterned layer of release material may therefore be reusable thus allowing it to be used repeatedly in several manufacturing cycles and avoiding the additional processing that would otherwise be required to form a release layer for every batch of ICs.

Patterning of the release layer also allows the option to use the debonding layer as a ‘photomask’ for patterning the substrate. Patterning the substrate prior to IC formation (whether using the debonding layer as a ‘photomask’ or via some other similar process) beneficially avoids the need for potentially time-consuming and contaminant creating singulation processes (e.g., using water jets or lasers).

### Carrier Processing and Subsequent IC Formation

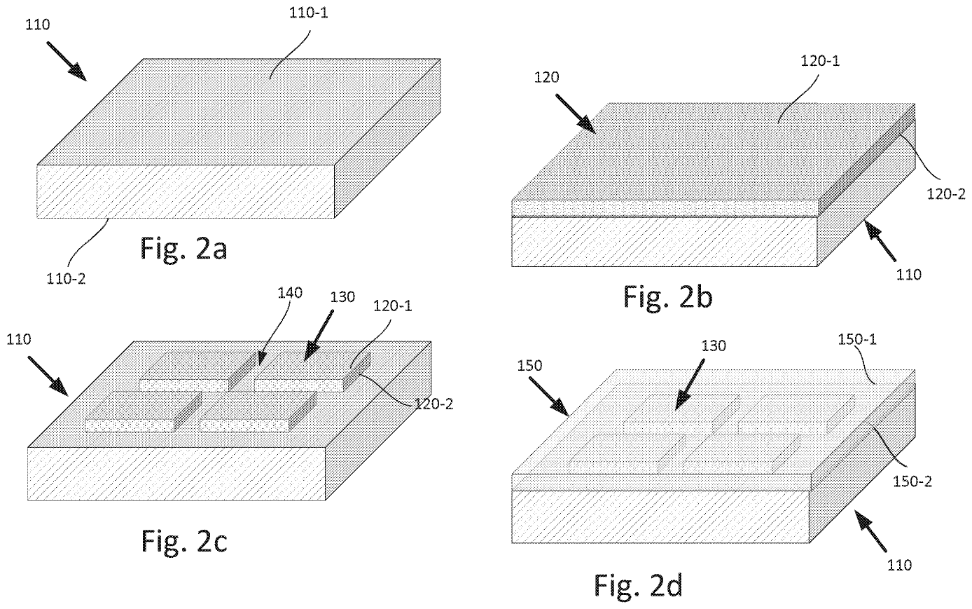

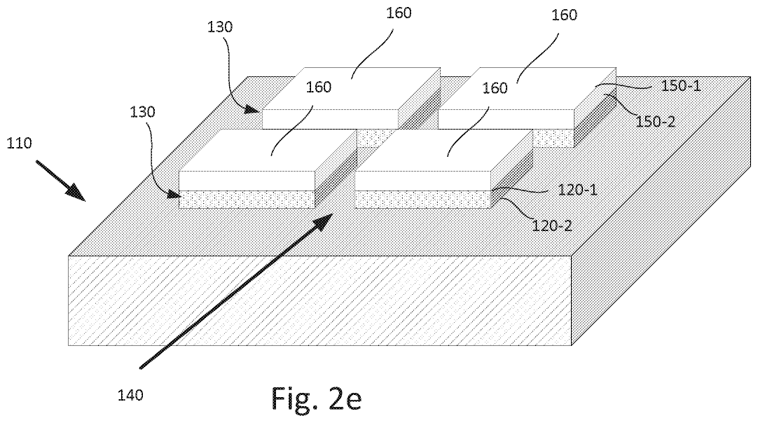

Formation of a plurality of discrete integrated circuits (ICs) on a patterned substrate on the carrier 110 having a patterned release layer, such as that described with reference to FIG. 1, will now be described in more detail by way of example only, with reference to FIGS. 2a-2e. It will be appreciated that FIGS. 2a-2e are purely illustrative. In this, and the other described examples, the substrates are flexible. Nevertheless, non-flexible (rigid) substrates may be provided on the carrier for the formation of the ICs. The techniques disclosed are, nevertheless, particularly advantageous in the context of flexible substrates.

As shown in FIG. 2a, a blank carrier 110 is initially provided for processing during IC fabrication, to provide a (potentially reusable) base structure for providing support for the ICs as they are fabricated. As described above, the carrier 110 may be a rigid carrier formed from any suitable material such as glass, polycarbonate, quartz, silicon, or any other known materials suitable for supporting a substrate upon which discrete ICs are formed. The carrier can be any shape suitable for manufacturing purposes.

It will be appreciated that the thickness of the carrier 110 will be dependent on the material used, its respective transparency to the radiation being used to induce release, and hence on the wavelength of that radiation. By way of example only, the carrier 110 may have a thickness of, for example, between 300 μm and 1.6 mm, or for example between 400 μm and 1.5 mm, or for example between 500 μm and 1.4 mm, or for example between 600 μm and 1.3 mm, or for example between 700 μm and 1.2 mm, or for example between 800 μm and 1.1 mm, or for example between 900 μm and 1 mm. For example, the thickness of the carrier may be between 500 μm and 1 mm. The carrier 110, in this example, is generally planar having a first surface 110-1 (uppermost in FIG. 2a) and a second surface 110-2 opposite to the first surface 110-1.

As shown in FIG. 2b, a layer of the release material (debonding layer) 120 is provided on the first surface 110-1 of the carrier 110 for aiding the later release and removal of ICs formed on the carrier 110.

While the exemplary debonding layer 120 may be formed of metals, metal oxides or metal alloys, the debonding layer 120 may be formed of any material that facilitates controlled release of the substrate (e.g., by absorbing light and converting it to heat), and hence the discrete ICs, from the carrier. The debonding layer 120 provided on the first surface 110-1 of the carrier 110 may be a layer of uniform thickness and which uniformly covers the first surface 110-1 of the carrier 110 as shown in FIG. 2b. Advantageously, the release material and the thickness of debonding layer 120 may be configured to mitigate the risk that the absorbed electromagnetic radiation causes damage to the debonding layer 120. Hence, the debonding layer 120 may be reusable even after it has been heated up by electromagnetic radiation.

The debonding layer 120 may be provided using any suitable method, for example by sputtering directly onto the carrier 110. It will, nevertheless, be appreciated that the debonding layer 120 may be formed on one or more other, intermediate, layers formed on the carrier 110.

The debonding layer 120 may be formed of any suitable ‘release material’. The release material may, for example, include any number or combination of metals. Typically, where the debonding layer 120 is metal, the metal may be selected from one or more of: Hafnium (Hf), Vanadium (V), Niobium (Nb), Tantalum (Ta), Titanium (Ti), Tungsten (W), Molybdenum (Mo), Aluminium (Al), Copper (Cu), Gold (Au), Silver (Ag), Iron (Fe), Tin (Sn), Zinc (Zn), Cobalt (Co), Chromium (Cr), Germanium (Ge), Palladium (Pd), Platinum (Pt), Rhodium (Rh), Manganese (Mn), Nickel (Ni), Silicon (Si), Tellurium (Te), oxides of the foregoing, and alloys of the foregoing. For example, the debonding layer 120 may be formed from one or more metals of: groups 4, 5, and 6 of the IUPAC periodic table, oxides thereof, and alloys thereof. For example, the debonding layer may be formed of one or more of Hafnium (Hf), Vanadium (V), Niobium (Nb), Tantalum (Ta), Chromium (Cr), Molybdenum (Mo), Titanium (Ti), or Tungsten (W), oxides thereof, and alloys thereof. Debonding layers formed from Ti, W, TiW, or Mo have been found. to be particularly beneficial for facilitating a controlled release of the substrate material. Throughout the remainder of the description chemical symbols for elements will be used in place of full chemical names. It will be appreciated that the metals listed are only examples of metals that can be used for the debonding layer 120 and that the use of other metals is not precluded.

The debonding layer 120 when deposited may be any suitable thickness for providing a required partial transparency. For example, the debonding layer may have a thickness of between 20 nm and 300 nm, such as between 21 nm and 250 nm, between 22 nm and 200 nm, between 23 nm and 150 nm, between 24 nm and 100 nm, between 25 nm and 90 nm, between 26 nm and 80 nm, between 27 nm and 70 nm, between 28 nm and 60nm, between 29 nm and 50 nm, or between 30 nm and 40 nm. For example, the thickness of the debonding layer may be between 25 nm and 35 nm, or between 150 nm and 200 nm. For example, for a release material formed from Mo or an oxide or an alloy thereof, a debonding layer 120 having a thickness of less than 30 nm has been found to be effective, such as thickness of between 20 nm and 30 nm. For example, for a release material formed from TiW, a debonding layer 120 having a thickness of between 150 nm and 200 nm has been found to be effective It will be appreciated however that the thickness of the deposited debonding layer may vary depending on the material used for the debonding layer 120. In more detail, as indicated previously the debonding layer 120 is provided to facilitate the controlled release of the substrate, and hence the discrete ICs formed on the substrate, from the carrier 110. One way of facilitating controlled release of the substrate is to optically induce the release by photonic ablation. For example, the debonding layer 120 may be irradiated from the second surface 110-2 of the carrier 110 (i.e., from beneath the carrier 110 in the illustrated example) such that some of the radiation (but not all) is transmitted through the debonding layer 120 to the substrates formed above. By controlling the amount of radiation reaching the substrates the amount of damage caused by the radiation to the substrates is minimised, thereby improving the release process. It will be appreciated however that to ensure that only some of the radiation (and not all) is transmitted through the debonding layer 120, in some examples, the material used for the debonding layer is partially transparent to the radiation being used. It will thus be appreciated that the thickness of the debonding layer 120 will be dependent on the material used, its respective transparency to the radiation being used to induce release, and hence on the wavelength of that radiation.

Additionally, the thickness of the debonding layer 120 may be selected based on the transmission and absorption requirements of the material during lithography processes to facilitate the manufacturing of the layers needed to form the discrete ICs on the carrier 110. For example, during manufacture, as described in more detail below, the debonding layer 120 and the IC areas 130 formed therefrom may act as an in-situ photomask. That photomask may in turn be used to assist in the patterning of the IC substrates 160 through photoresist lithography. It will thus be appreciated that the thickness of the debonding layer 120 may also be dependent on the material used and its respective transparency to the radiation being used to form flexible IC substrates 160 through photoresist lithography.

Additionally, it will be appreciated that the thickness of the debonding layer 120 may be selected based on a compromise between its transparency to the radiation being used to induce release of the IC substrates 160, and the transmission and absorption requirements of the debonding layer 120 during lithography processes.

The debonding layer 120 has a first surface 120-1 (uppermost in FIG. 2b) and a second surface 120-2, opposite to the first horizontal surface 120-1, forming an interface with the carrier 110 (or intermediate layer if present).

As shown in FIG. 2c, during the manufacturing process, the debonding layer 120 may be patterned using any suitable technique, for example using conventional photoresist-based lithography and etching with a suitable etchant, to form the IC areas 130 corresponding to the locations in which the ICs will be fabricated on the carrier 110. A number of intermediate regions 140 (referred to as ‘bridging’ areas/regions, ‘dice lanes’or ‘dice lines’) are provided between the IC areas 130 (and potentially adjacent the IC areas 130 at the edge of an array of IC areas 130).

Whilst the IC areas 130 depicted in FIGS. 1 and 2 are planar square IC areas 130, it will be appreciated that they may adopt any appropriate planar shape that fits with application constraints of the IC that is being manufactured. They may, for example, be rectangular, more broadly quadrilateral, triangular, hexagonal, elliptical, or any of a multitude of more complex shapes. Examples of other possible shapes are described in more detail later.

As shown in FIG. 2c, the debonding layer 120 is patterned such that there is no release material in the intermediate regions 140. Nevertheless, it will be appreciated that there may be a thinner layer of release material in the intermediate regions 140. Moreover, as described in more detail later, the intermediate regions 140 may include areas of different thicknesses of release material and/or areas with and without release material present (e.g., to provide a base for one or more test structures and/or to provide for perforations to be formed between the substrates of adjacent ICs).

It will be appreciated that the debonding layer 120 may not be patterned using conventional photoresist-based lithography and etching but may be formed pre-patterned on the carrier 110. For example, prior to depositing the debonding layer 120 a non-stick (non-adhesive) ‘template’ layer may be overlaid on to the first surface 110-1 of the carrier which comprises an inverse or ‘negative’ of the desired pattern of the debonding layer 120. For example, in the case of FIG. 2c, there may be provided a non-stick layer (or mask layer) that comprises raised portions forming ‘frames’around four distinct windows or quadrants on the first surface 110-1 of the carrier 110. Once in place, the release material may be deposited using an appropriate deposition method (e.g., as described above). Hence, release material will be deposited in the four quadrants, and on top of the raised portions of the non-stick layer (or mask layer). Following deposition of the release material, the non-stick layer may be removed to form the debonding layer 120 comprising the four IC areas 130 and intermediate regions 140 between them (and around their edges).

As shown in FIG. 2d, a substrate layer 150 is provided on top of the IC areas 130 and the intermediate regions 140, (the substrate layer 150 is shown as semi-transparent in FIG. 2d for illustrative purposes only). The substrate layer 150 may be a blanket layer that covers all the IC areas 130 and intermediate regions 140. The substrate layer 150 may be a layer of a flexible polymer such as polyimide, or some other suitable substrate material. For example, other polymer materials may comprise polymers selected from one or more of: polyethylene naphthalates, polyethylene terephthalates; polymethyl methacrylates; polycarbonates, polyvinyl alcohols, polyvinyl acetates, polyvinyl pyrrolidones, polyvinyl phenols, polyvinyl chlorides, polystyrenes, polyimides, polyamides (e.g. Nylon); poly(hydroxy ethers), polyurethanes, polycarbonates, polysulfones, parylenes, polyarylates, polyether ether ketones (PEEKs); acrylonitrile butadiene styrene (ABS), 1-Methoxy-2-propyl acetates, Benzocyclobutenes (BCB), polylactic acid (PLA), polyhydroxyalkanoates (PHAs), polybutylene succinate (PBS), polybutylene adipate terephthalate (PBAT), cellulose polymers, or any other suitable polymer material.

The substrate layer 150 may be deposited using thin-film processes such as, for example: physical vapour deposition (e.g. sputter), chemical vapour deposition (e.g. plasma-enhanced chemical vapour deposition (PECVD)), vacuum deposition (e.g. thermal or electron-beam evaporation); coating (e.g. spin, dip, blade, bar, spray, or slot-die), printing (e.g. jet, gravure, offset, screen, or flexographic), pulsed-laser deposition (PLD), atomic layer deposition (ALD) and/or any other suitable processes.

It will be appreciated that although most of the examples presented above involve a flexible substrate layer 150 made of a polymer, the substrate layer 150 is not restricted to being a polymer. The substrate layer 150 may be formed from any other materials that provide suitable electrical, chemical, and/or structural properties. As such the substrate layer 150 may comprise materials selected from one or more of: flexible glass, polymer materials, metal oxide materials, resin materials, resist materials, foil materials, paper, insulator coated metals, or any other suitable material. It will be appreciated that the materials listed herein are only provided by way of example and are not an exhaustive list of possible materials that may be used for the substrate layer 150.

By way of example only, the substrate layer 150 may comprise metal oxides selected from one or more of: Al₂O₃, SiOₓN_{y}, SiO₂, Si₃N₄, or any other suitable metal oxide; or resins selected from one or more of: a UV-curable resin or any other suitable resin; or resists selected from one or more of: nanoimprint resists, photoresists such as, for example, Bisphenol A novolac epoxy (SU-8) or polyhydroxybenzyl silsesquioxane, or any other suitable resist; or foils selected from one or more of: polymeric foils or any other suitable foil; or insulator coated stainless-steel or any other suitable insulator-coated metal. It will be appreciated that the materials listed herein are only provided by way of example and are not an exhaustive list of possible materials that may be used for the substrate layer 150.

The substrate layer 150 may be 0.5-20.0 μm thick, and typically may be 1.0-10.0 μm thick. In certain circumstances the substrate layer 150 may be 5.0 μm.

The substrate layer 150 has a first surface 150-1 (uppermost in FIG. 2d) and a second surface 150-2 opposite to the first surface 150-1. The substrate layer is formed on the IC areas 130 and the intermediate regions 140, to form interfaces between the second surface 150-2 of the substrate layer 150, and the IC areas 130 and the intermediate regions 140, respectively.

Optionally, prior to depositing the substrate layer 150, a capping layer (not shown) may be deposited to cover the IC areas 130 (and intermediate regions 140). The capping layer may be a layer comprising any material that enhances the durability of the debonding layer 120 without negatively affecting its primary function. For example, the capping layer may be a layer of metals oxide such as, for example, SiOₓ or AlₓO_{y}. It will however be appreciated that SiOₓ or AlₓO_{y} are listed by way of example only and any material suitable for use as a capping layer may be used. A capping layer may be deposited to cover (or encapsulate) the IC areas 130 (and the intermediate regions 140) to protect the debonding layer 120. For example, the material of the capping layer may be selected to prevent electromigration processes in the intermediate areas when those intermediate areas comprise electrical components and/or electrical connection features. Alternatively, or additionally, prior to depositing the substrate layer 150, a treatment may be performed on the debonding layer 120 to enhance its durability.

As shown in FIG. 2e, during the manufacturing process, substrate layer 150 may be patterned, to form a plurality of distinct IC substrates 160, using conventional top-side photoresist-based lithography and etching with a suitable etchant. Alternatively, rear-side photoresist-based lithography processes may be used (as described in more detail below). However, irrespective of the method used to pattern the substrate layer 150, it is generally patterned in such a way as to provide the distinct IC substrates 160 on top of, and in alignment with the IC areas 130.

Following patterning of the substrates, a respective IC may be fabricated on each distinct IC substrate 160 using IC manufacturing steps that would be well understood by the person skilled in the art. Nevertheless, for completeness, a typical such manufacturing process is briefly described later by way of example only.

Once the ICs are complete, the IC substrates 160 on which the ICs are formed can be released from the IC areas 130. To release the IC substrate 160 a wavelength of electromagnetic radiation may be emitted onto the second surface 110-2 of the carrier 110. That electromagnetic radiation incident on the second surface 110-2 of the carrier 110 may pass (propagate) through the carrier and at least partially absorbed by the release material of the debonding layer 120, which may raise the temperature of the debonding layer 120. Nevertheless, sufficient optical energy passes through the debonding layer 120 to ablate the interface between the debonding layer 120 and the IC substrate 160 thereby reducing the strength of bonding between the debonding layer 120 and the IC substrate 160. Once the bonds between the debonding layer 120 and the IC substrate 160 are weakened, the IC substrate 160 may be peeled off the IC area 130 or lifted off the IC areas 130 via e.g., a pick-up process or apparatus.

### Debonding Layer Features

As mentioned above the intermediate regions 140 may include release material. This release material may be of the same or a different thickness to that of the IC areas 130 and configured for forming one or more debonding layer features of a range of types.

For example, the intermediate regions 140 may include debonding layer features that form links to one or more neighbouring IC areas, and/or debonding layer features upon which test structures are subsequently manufactured.

Advantageously, by patterning the debonding layer 120 so that the intermediate regions 140 include debonding layer features, the intermediate regions 140 may support electrical connections that extend across the substrate layer deposited on the flexible substrate thereby forming links between one or more neighbouring IC areas. This may, for example, help with electrostatic clamping (chucking/dechucking) during any subsequent plasma processing that may be used during the IC substrate deposition (?) and IC fabrication.

Advantageously, the intermediate regions 140 may also act as exit paths for any gases produced during the release of the IC substrates 160 from the IC substrate areas 130. This has the potential to mitigate the risk of any shock wave effects that may arise as a consequence of a build-up of such gases during the release process of the IC substrates 160.

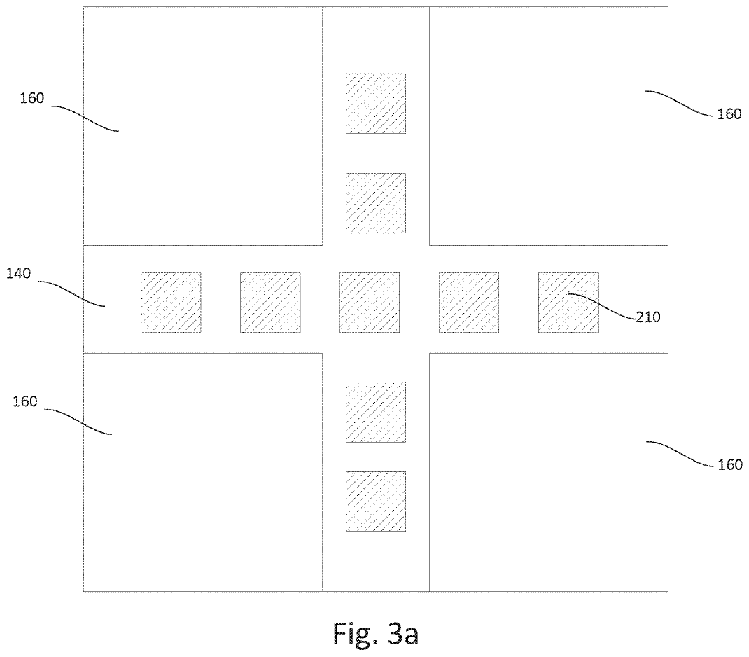

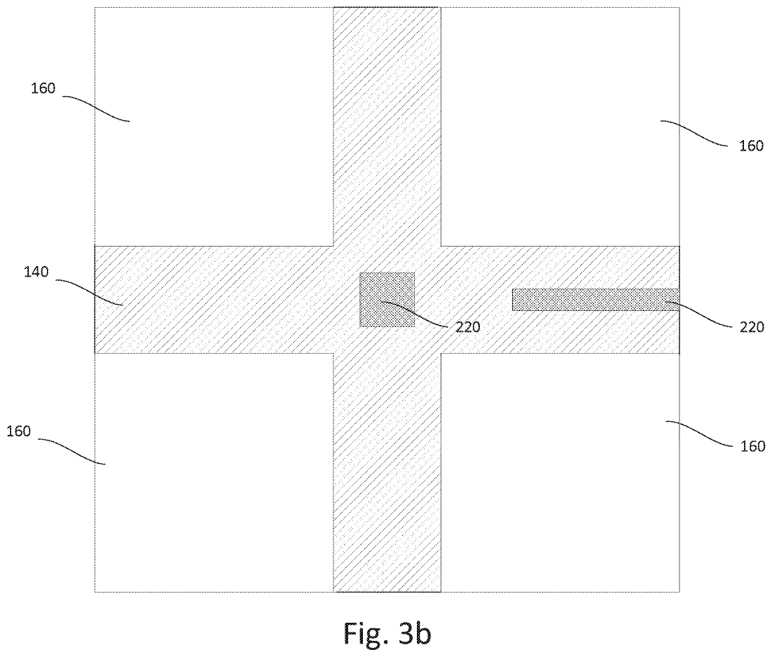

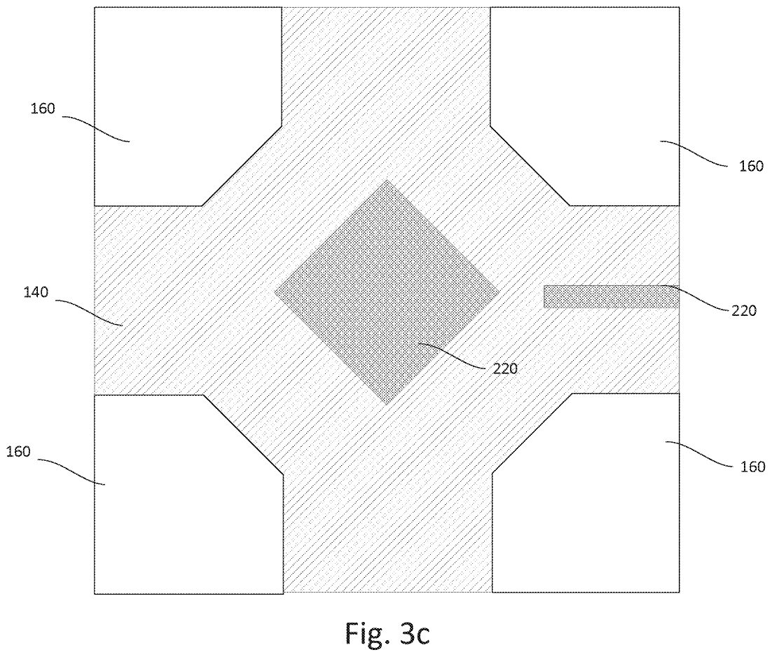

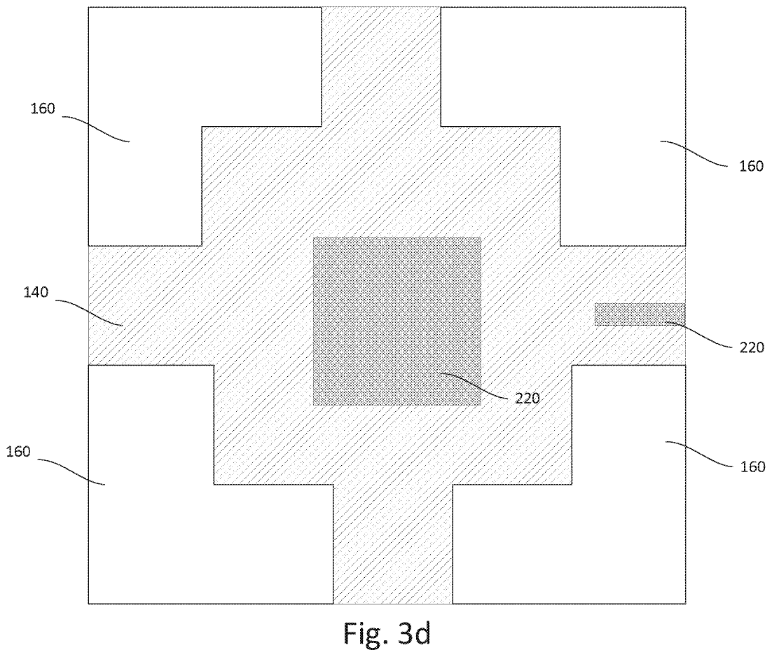

Examples of some of the debonding layer features that may be formed in the intermediate regions 140 are depicted in FIGS. 3a-3c.

As shown in FIG. 3a, the debonding area 120 may include debonding layer features in the form of linear repeating patterns of ‘patches’or ‘windows’210, in which there is no release material (or a thinner layer of release material than that of the surrounding area), located in the intermediate regions 140. The release material of the intermediate region 140 surrounding the patches 210 may be of the same, or a different, thickness to that of the IC areas 130. Each pattern of patches 210 respectively extends generally parallel to the edge(s) of the IC area(s) 130 (and hence IC substrate(s) 160) adjacent (or between) which that pattern of patches 210 is located. The patches 210 may be formed through conventional photoresist-based lithography and etching by a suitable etchant of the debonding layer. For example, using etching, the entire thickness of debonding layer is removed to form the series of patches 210 to expose the underlying carrier 110.

The pattern of patches 210 in FIG. 3a provides for perforations in the substrate material between different IC substrates 160 which can aid singulation and separation of the individual IC substrates 160 from one another and individual removal from the carrier 110. For example, separation of an IC substrate 160 may be achieved by ‘tearing’ or ‘snapping’ of the substrate along one or more lines extending parallel to the intermediate region 140 adjacent that IC substrate 160.

It can be seen therefore that while, in the example described with respect to FIGS. 2a-2e, the debonding area 120 may be etched to form intermediate region 140 in which there is no release material, in this example (shown in FIG. 3a) part of the intermediate regions 140 include release material which may be of the same thickness as the IC areas. Thus, by using the patterns of patches 210 the amount of material that needs to be removed in intermediate regions 140 is beneficially reduced.

Alternatively, or additionally, as shown in FIGS. 3b-3d, the release material of the intermediate regions 140 may be patterned using any of the previously mentioned patterning processes to form one or more test structure areas 220 of release material for supporting a corresponding test structure. The test structures may, for example, include fiducials for alignment of masks, electrical components such as resistors, capacitors, transistors, or combinations thereof, and/or circuits such as ring oscillators. Accordingly, the test structures may enable the testing and verification of the pattern alignment and/or etching for one or more layers of the IC substrate 160 and or the IC itself during its formation. For example, the test structures may be used to ensure each layer is patterned and formed in alignment with previously deposited layers.

Alternatively, or additionally, the test structures can be used to provide(?) information on the status, condition or any other aspect of the process, devices, circuits and/or any other feature or stage of the fabrication process.

It can be seen, therefore, that the test structure(s) in this example are singulated and may be removed from the carrier 110 separately from the ICs, relatively easily, by virtue of the area of release material on which it is fabricated. It will, nevertheless, be appreciated that one or more test structures may, alternatively or additionally, be formed on a substrate in an area of an intermediate region 140 that has not been patterned to include any release material. For example, one or more test structures may be formed on substrate material in the intermediate region 140 that are configured to remain attached to the carrier when neighbouring ICs are released (e.g., to avoid the test structure(s) being transferred with an IC and inadvertently attached to the structure that IC is being transferred to).

As is shown in FIGS. 3b-3d, the test structure areas 220 may take a variety of forms or shapes. By way of example only, in FIG. 3b the test structure areas 220 may comprise a square test structure area 220 in the centre of the intermediate region 140, and a rectangular test structure area 220 extending away from the square test structure area 220 between adjacent IC areas. The remainder of the intermediate region 140 is devoid of any release material, or other deposited material (i.e., the remainder of the intermediate region 140 as shown in FIG. 3b comprises the exposed surface of the carrier 110). By way of example only, in FIG. 3c the test structure areas 220 comprise a square test structure area 220 in the centre of the intermediate region 140 which has been rotated through an angle of 45 degrees relative to the IC areas (and IC substrates 160 when formed). In this example, the IC areas (and corresponding IC substrates) are not completely square but have corners chamfered at 45° (hence maintaining a constant distance between the IC area/substrate and the square test structure area 220). As in FIG. 3b, in this example, a rectangular test structure area 220 is also present extending, between two adjacent IC areas, away from one corner of the square test structure area 220. The remainder of the intermediate region 140 is devoid of any bonding layer material, or other deposited material. In the example shown in FIG. 3d the test structure areas 220 are similar to that shown in FIG. 3b, comprising a square test structure in the centre of the intermediate region 140 and a rectangular test structure area 220 extending away from the square test structure area 220. In this example, however, the IC areas (and corresponding IC substrates) are not completely square but have portions of their corners removed to maintain a minimum distance between the IC area/substrate and the square test structure area 220 and allowing for a test structure area that is larger than the distance between adjacent IC areas. The remainder of the intermediate region 140 is devoid of any bonding layer material, or other deposited material. It will be appreciated that in the examples shown in FIGS. 3b-3d the different shapes of the IC areas/IC substrates are purely exemplary.

It will also be appreciated that the number and shape of the test structure areas 220 may vary beyond that depicted in FIGS. 3b-3d and that those test structures 220 are only shown as examples. Furthermore, it will be appreciated that although in FIGS. 3b-3d the test structure areas 220 are shown to be in intermediate areas 140 devoid of any other deposited materials, this need not be the case.

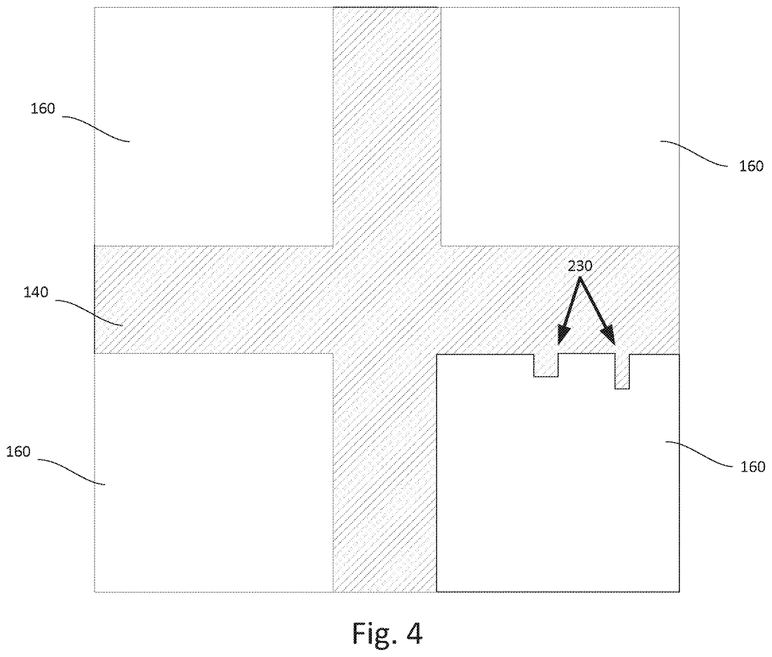

As shown in FIG. 4 the release material may be patterned to form one or more debonding layer ‘edge’ features that are not located in the intermediate region 140 but, instead, extend into one or more edges of one or more IC areas (and hence, IC substrate(s) formed on the IC area(s)). For example, as seen in FIG. 4, debonding layer features may be formed by etching indentations/recesses 230 into the edges of one or more IC areas (and hence IC substrates 160) so as to expose the carrier 110 below. Those indentations result in the IC area, and corresponding IC substrate 160, having a profiled edge. This profiled edge may be configured to act as a unique identifier - for example of the specific carrier on which the ICs are being fabricated. Alternatively, the profiled edge may be unique to a batch of ICs and/or IC substrates. It will be appreciated that the profiled edge depicted in FIG. 4 is provide by way of example only and other types of profiled edge may be provided.

### Alternative IC Area and IC Substrate Shapes

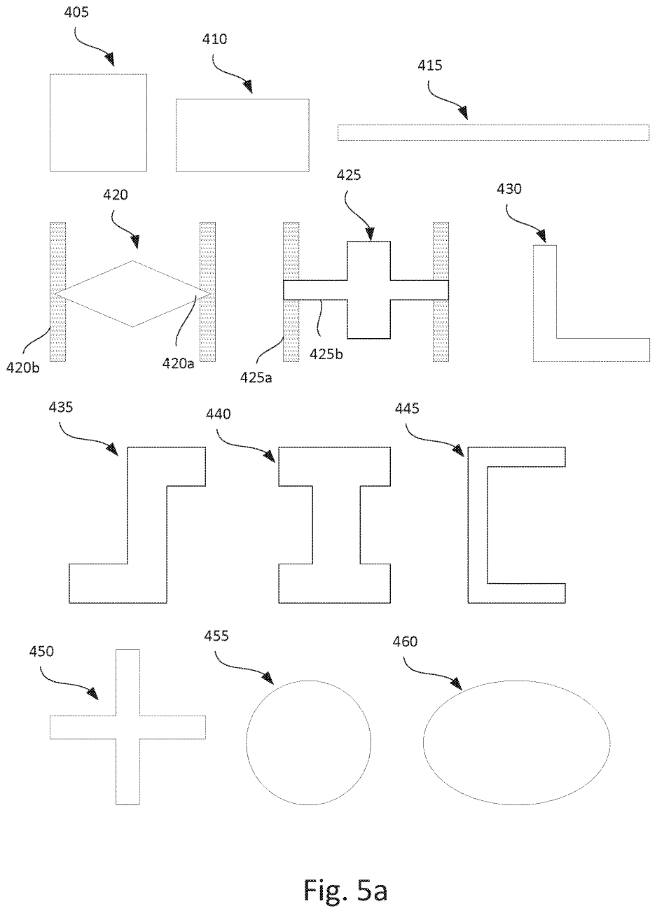

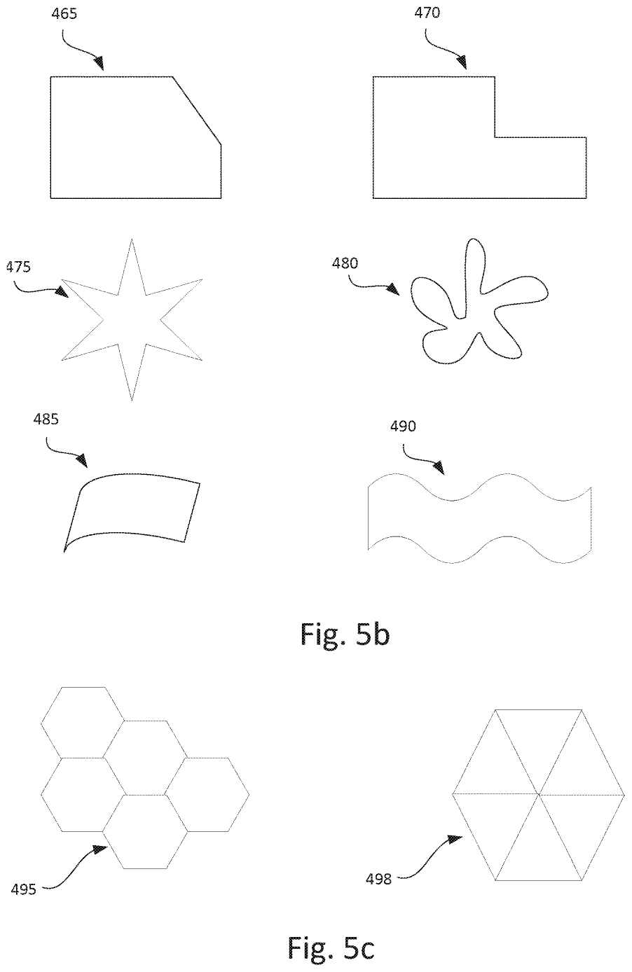

The IC areas 130 and IC substrates 160 described thus far are planar and generally square. It will be appreciated however that planar square IC areas and substrates are only one example of a type, and shape of IC area and substrate. As shown in FIGS. 5a-5c the shape of the IC areas, IC substrates, and thus the shape of the ICs formed upon those substrates may take any number of different shapes.

As shown in FIG. 5a a large range of shapes may be used for the IC areas and substrates including, but not limited to, squares 405, rectangles 410; 415, rhombi 420, cross-type shapes 425; 450, “L” shapes 430; 470, straight edged “S” shapes 435 (or “Z” shapes), “I” shapes 440, straight edged “C” shapes 445, circles 450, or ovals 455.

Alternatively, as shown in FIG. 5b the shape of the IC areas and substrates may be less regular such as trapezoidal-type shapes 465, star shapes 475, or wave-like shapes 485; 490. Alternatively, the shape of IC areas and substrates may be completely irregular such as shape 480.

It will be appreciated that the shapes shown in FIGS. 5a & 5b are provided as examples only and are not an exhaustive set of possible shapes.

As shown in FIG. 5 a, with reference to shapes 420 & 425, the shape may be designed such that it may have two or more electrical contact points that contact with corresponding electrical contacts in an application, device, apparatus, or the like. For example, as shown in FIG. 5a the rhombus 420 has two points at two of its extremities 420a which provide two electrical contact points. Those electrical contact points 420a may connect to corresponding electrical contact points 420b of a circuit. Similarly, the cross-type shape 425 has two points at two of its extremities 425a which provide two electrical contact points, which may connect to corresponding electrical contact points 425b of a circuit. It will be appreciated that the any of the shapes shown in FIGS. 5a & 5b may be configured such that they have two or more electrical contact points that may be configured for connection to a circuit.

As shown in FIG. 5c any tessellating shape may be used to help ensure efficient use of the substrate. In this way, substrate wastage may be minimised. For example, the tessellating shapes may include straight-sided geometries such as regular or irregular triangles 498, pentagons, hexagons 495, squares, rectangles, or any other form of polygon that can be arranged into a tessellating pattern. It will be appreciated that the two tessellating shapes shown in FIG. 5c are provided as examples only and are not an exhaustive set of possible tessellating shapes. It will also be appreciated that any of the tessellating shapes shown in FIG. 5c may be configured such that they have two or more electrical contact points that may be configured for connection to a circuit.

### Fabrication of the (Flexible) ICs

As described above, once the substrates 160 have been patterned onto the IC areas 130 IC fabrication can proceed as usual on the patterned substrate areas. This typically involves formation of a component layer comprising electronic components and associated interconnections formed by deposition and patterning of successive thin film layers using front end of line (FEOL) processing and back end of line (BEOL) processing.

The FEOL processes apply layers of semiconductor, conductor, dielectric and other insulation materials in order to form electronic devices such as, for example, transistors, diodes, capacitors, resistors, conductive tracking and other electronic components and devices.

The BEOL processes apply layers of conductor and insulator/dielectric materials, for example to form interconnects between the FEOL components and devices and contact structures (and other similar components), and to provide insulation between different layers and structures where required.

Optionally, once the substrate layer has been patterned to form IC substrates 160, a barrier layer may be deposited on the IC substrates 160 before formation of the component layer. Although the use of a barrier layer may allow for improved formation of the component layer, the use of a barrier layer is not essential and the component layer may be formed directly onto the IC substrates 160. The barrier layer may be deposited using any of the thin-film processes that were described above. The barrier layer may comprise one or more layers of dielectric materials. The one or more layers of dielectric materials may be formed using the same or different thin-film processes and/or the same or different processing conditions. If the barrier layer comprises one or more layers of dielectric materials, the materials may be selected from one or more of: metal oxides, metal phosphates, metal sulphates, metal sulphites, metal nitrides, metal oxynitrides, inorganic insulators, spin-on glass, polymeric dielectric materials, UV-curable resins, nanoimprint resists, photoresists or any other suitable dielectric material.

By way of example only, the barrier layer may comprise one or more of: metal oxides such as Al₂O₃, ZrO₂, HfO₂, Y₂O₃, Si₃N₅, TiO₂, Ta₂O₅ or any other suitable metal oxide; or metal phosphates such as Al₂POₓ or any other suitable metal phosphate; metal sulphates or metal sulphites such as HfSOₓ or any other suitable metal sulphate or metal sulphite; metal nitrides such as AlN, TiN, ZrN, TaN, HfN or any other suitable metal nitride; metal oxynitrides such as AlOₓN_{y} or any other suitable metal oxynitride; inorganic insulators such as SiO₂, Si₃N₄, SiNₓ or any other suitable inorganic insulator; spin on glass such as polyhydroxybenzyl silsesquioxane or any other suitable spin on glass; or polymeric dielectric materials such as amorphous fluoropolymers (Cytop®), Bisphenol A novolac epoxy (SU-8), benzocyclobutenes (BCB), polyimides, polymethyl methacrylates, polybutyl methacrylates, polyethyl methacrylates, polyvinyl acetates, polyvinyl pyrrolidones, polyvinyl alcohols, polyvinyl phenols, polyvinyl chlorides, polystyrenes, polyethylenes, polycarbonates, parylenes, silicone, or any other suitable polymeric dielectric materials. It will be appreciated that the materials listed herein are only provided by way of example and are not an exhaustive list of possible materials that may be used for the barrier layer.

The barrier layer may comprise a dielectric with a relatively low dielectric constant κ (low-κ) such as Cytop®, polyhydroxybenzyl silsesquioxane, parylenes), or any other suitable low-κ material. Alternatively, the barrier layer may comprise a dielectric with a relatively high dielectric constant κ (high-κ) such as Ta₂O₅, HfO₂, or any other suitable high-κ materials, insulating oxides, oxynitrides, or silicates.

Alternatively, the barrier layer may be formed from one or more layers of metal such as, for example, Ti, Au, steel, or any other suitable metal.

The component layer may be formed on the barrier layer, or alternatively directly on the IC substrates 160 if no barrier layer is provided. The component layer may include electronic components of the IC, including active, passive, conducting, insulating, and contact components. The component layer may comprise one or more layers that are sequentially formed using any of the aforementioned thin-film deposition and patterning processes, or any other suitable fabrication processes, where each layer may include one or more of active, passive, conducting, insulating, and contact components. Alternatively, the component layer may be referred to as the active layer.

The component layer may also include a contact layer that provides contacts for mechanically and/or electrically connecting the ICs to external circuitry, such as, for example, an application item or any other external structure. The contact layer may be positioned at or towards the upper and/or lower surfaces of the component layer. The contacts may be connection pads or contact members. It will be appreciated that the number of contact members is variable, and, optionally, no contact members may be included in the IC. Other surfaces of the IC may also include one or more contact members, if desired. The contact members may be raised, recessed or substantially planar with the respective surface of the IC.

The component layer may comprise one or more layers of conductive materials. Conductive materials may be selected from one or more of: metals, metal alloys, transparent conductive oxides, metal nitrides, carbon materials, conducting polymers, semiconductor materials, or any other suitable conducting material.

By way of example only, conductive materials used for the component layer may be selected from one or more of: metals such as Au, Ti, Al, Mo, Pt, Pd, Ag, Cu, Ni, Cr, Ta, W or any other suitable metal; metal alloys such as MoNi, MoCr, AlSi or any other suitable metal alloys; or transparent conductive oxides such as ITO, IZO, AZO, or any other suitable transparent conductive oxide; metal nitrides such as TiN or any other suitable metal nitride; carbon materials such as carbon black, carbon nanotubes, graphene or any other suitable carbon material; or conducting polymers such as polyaniline, poly(3,4-ethylenedioxythiophene) polystyrene sulfonate (PEDOT: PSS) or any other suitable conducting polymer. It will be appreciated that the materials listed herein are only provided by way of example and are not an exhaustive list of possible materials that may be used for the component layer.

The component layer may comprise one or more layers of semiconductor materials. Semiconductor materials may be selected from one or more of: compound semiconductors, metal oxides, metal oxynitrides, inorganic semiconductors, organic semiconductors, polymer semiconductors, 2D semiconductor materials, chalcogenides, perovskites, or any other semiconductor material.

By way of example only, semiconductor materials used for the component layer may be selected from one or more of: GaAs, GaN, InP, CdSe, InGaAs, InGaAsSb, ZnO, SnO₂, NiO, SnO, Cu₂O, In₂O₃, LiZnO, ZnSnO, InSnO (ITO), InZnO (IZO), HfInZnO (HIZO), InGaZnO (IGZO) ZnₓO_{y}N_{z} amorphous, microcrystalline or nanocrystalline Si, Copper(II) phthalocyanine (CuPc), pentacene, perylenetetracarboxylic dianhydride (PTCDA), methylene blue, Orange G, rubrene; PEDOT: PSS, poly(3-octylthiophene) (POT), poly(3-octylthiophene-2,5-diyl) (P3OT), poly(3-hexylthiophene) (P3HT), polyaniline, polycarbazole, grapheneMoS2, GeSbTeSrTiO₃, CH₃NH₃PbCl₃, H₂NCHNH₂PbCl₃, CsSnI₃, or any other suitable semiconductor material. It will be appreciated that the materials listed herein are only provided by way of example and are not an exhaustive list of possible materials that may be used for the component layer.

The semiconductor material used for the component layer may also be doped or contain a doping gradient and may be n-type or p-type. Further treatments may be applied to the component layers to modify their semiconductor properties such as, for example, thermal or laser annealing, or any other known processes.

Optionally, one or more shielding layers may be provided in between, for example, the barrier layer and the component layer, and/or in between the component layer and the air. Alternatively or additionally, one or more shielding layers may be provided between different conducting layers. Such shielding layers may comprise one or more shielding metal layers. Shielding metal layers may serve, for example, to reduce any unwanted coupling between components.

### Method of Forming the (Reusable) Base

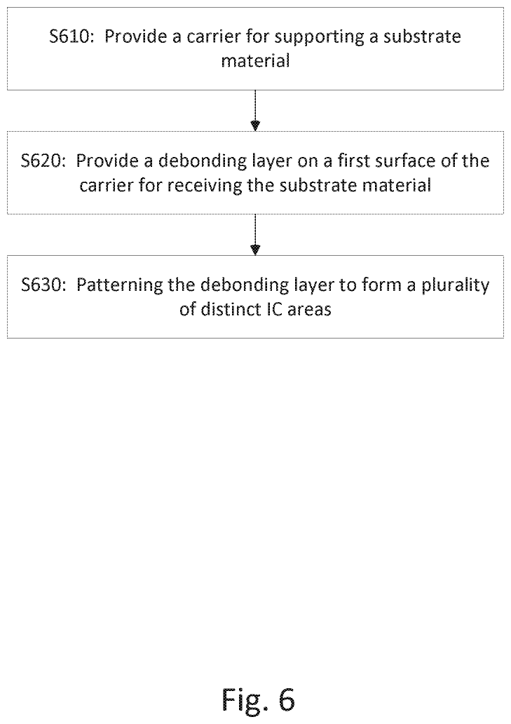

FIG. 6 is a simplified flow diagram illustrating a method of processing a carrier to form a (reusable) base for supporting a plurality of integrated circuits, ICs, during fabrication and for aiding release of the ICs following fabrication.

As seen in FIG. 6, at S610 a carrier is initially provided for supporting the substrate material. The carrier may for example be a glass carrier, such as a glass disk or of another form or material as described previously.

At S620, release material is deposited to form a debonding layer on a first surface of the carrier. The debonding layer may be formed of any appropriate material as described previously such as, for example, a metal selected from one or more of: Hafnium (Hf), Vanadium (V), Niobium (Nb), Tantalum (Ta), Titanium (Ti), Tungsten (W), Molybdenum (Mo), Aluminium (Al), Copper (Cu), Gold (Au), Silver (Ag), Iron (Fe), Tin (Sn), Zinc (Zn), Cobalt (Co), Chromium (Cr), Germanium (Ge), Palladium (Pd), Platinum (Pt), Rhodium (Rh), Manganese (Mn), Nickel (Ni), Silicon (Si), Tellurium (Te), oxides of the foregoing, and alloys of the foregoing.

The provision of the debonding layer may comprise depositing the release material using any appropriate thin-film process such as, for example: physical vapour deposition (e.g. sputter), chemical vapour deposition (e.g. plasma-enhanced chemical vapour deposition (PECVD)), vacuum deposition (e.g. thermal or electron-beam evaporation); coating (e.g. spin, dip, blade, bar, spray, or slot-die), printing (e.g. jet, gravure, offset, screen, or flexographic), pulsed-laser deposition (PLD), atomic layer deposition (ALD) and/or any other known processes.

At S630 the debonding layer is patterned to form the IC areas for supporting corresponding IC substrates during IC fabrication. The patterning of the debonding layer may be performed using the aforementioned patterning processes, or any other suitable patterning process. For example, the debonding layer may be patterned using top-side photoresist-based lithography and etching, or rear-side photoresist-based lithography. The patterning of the release material may, for example, comprise applying a photoresist (negative or positive) to the release material, applying electromagnetic radiation to the release material through an appropriate photomask for selectively exposing the photoresist to the applied electromagnetic radiation, removing the photoresist to define a pattern to be etched in the debonding layer, and etching the release material where the photoresist has been removed.

The patterning of the debonding layer also results in the formation of the intermediate regions 140 between adjacent IC areas.

### Method of Forming the ICs

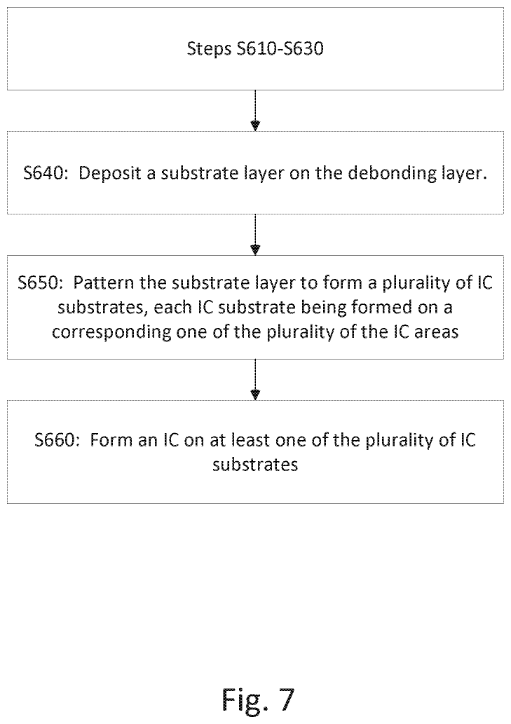

FIG. 7 is a simplified flow diagram illustrating a method of manufacturing ICs on a (reusable) base (e.g., formed using the process illustrated in FIG. 6) comprising a carrier and patterned debonding layer.

As seen in FIG. 7, at S640 a layer of substrate material is formed on the base comprising the carrier and patterned debonding layer (i.e., over the IC areas described previously).

At S650, the substrate layer is patterned to form a plurality of discrete IC substrates, each IC substrate being formed on a corresponding one of the plurality of IC areas. The patterning of the debonding layer may be performed using any of the aforementioned patterning processes, or any other suitable patterning process. For example, the substrate layer may be patterned using top-side photoresist-based lithography and etching, or rear-side photoresist-based lithography.

Nevertheless, it is particularly beneficial, when patterning the substrate layer, to pattern the layer using rear-side photoresist-based lithography. For example, the substrate layer may be patterned through the reverse side of the carrier (the side of the carrier opposite to the side for supporting the IC substrates). The patterning may occur either i) directly when the substrate layer is photo-imageable, or ii) by depositing a photoresist) which is then exposed through the intermediate regions. In both scenarios the debonding layer, and thus the formed IC areas function as an in-situ photomask which blocks the UV light during photolithography. Advantageously, this can improve the alignment of the IC areas and the IC substrates. Alternatively, as already indicated, more conventional photolithography methods may be used such as conventional top-side exposure photolithography.

At S660, ICs are formed on the requisite IC substrates, for example, by forming a component layer defining a circuit on the IC substrate (or possibly on a barrier layer on the IC substrate if present).

### Debonding/Releasing IC Substrates

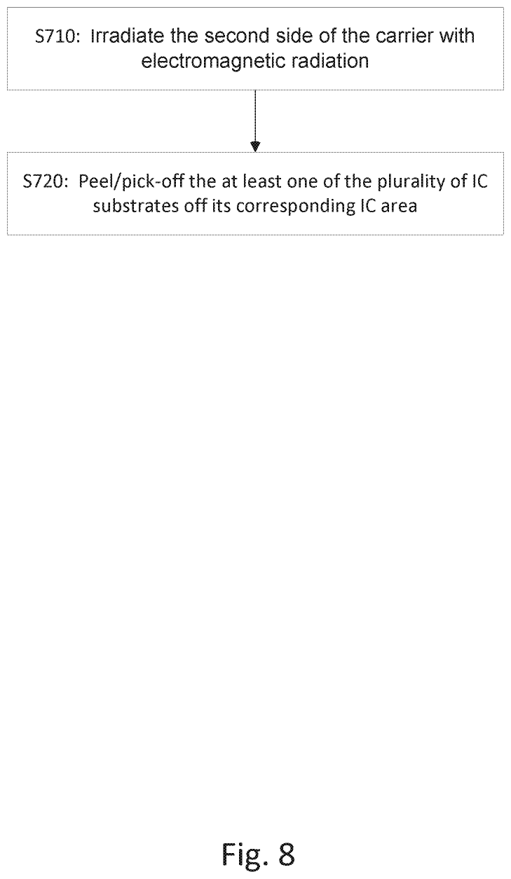

FIG. 8 is a simplified flow diagram illustrating a method of releasing (‘debonding’) the IC substrates.

As seen in FIG. 8, at S710, after a plurality of ICs have been formed (e.g., using the process illustrated in FIG. 7) on a (reusable) base (e.g., formed using the process illustrated in FIG. 6), the reverse side of the carrier (the side of the carrier opposite to the side for supporting the IC substrates) is irradiated with a specific wavelength of electromagnetic radiation. For example, it may be irradiated with electromagnetic radiation from a laser, flashlamps, high-powered LED, infrared radiation source, or other suitable sources of electromagnetic radiation as described previously.

As described above, the carrier is configured such that specific wavelengths of electromagnetic radiation may pass through (propagate through) the carrier upon it being irradiated. The wavelength of the electromagnetic radiation used may, for example, be in the ultraviolent range of the electromagnetic spectrum (100-400 nm). It may be particularly advantageous for the electromagnetic radiation used to be in the deep ultraviolet range of the electromagnetic spectrum (approx. 200-280 nm).

Upon incidence at the interface between the carrier and the debonding layer, the electromagnetic radiation may continue to propagate across said interface and through the debonding layer toward the interface between the debonding layer and the IC substrate. As the electromagnetic radiation passes through the debonding layer it is partially absorbed by the debonding layer such that the energy of the electromagnetic radiation wave when entering the debonding layer is greater than the energy of the electromagnetic radiation wave when it reaches the interface between the debonding layer and the IC substrates. The energy of the electromagnetic radiation wave reaching that interface may be such that it may gently heat up the release material of the debonding layer at that interface. Therefore, upon being irradiated the debonding layer acts as a buffer layer that absorbs some (but not all) of the radiation. Hence, the radiation reaching the interface between the debonding layer and the IC substrate is less likely to cause damage to the IC substrate.

Upon gentle heating of the interface between the debonding layer and the IC substrates, the strength of the bond between the IC substrate and the release material of the debonding layer is reduced (or in some circumstances the bond may be completely broken), thereby releasing the IC substrate from the debonding layer.

At S720, once the IC substrate has been released from the debonding layer it is subsequently peeled off (or otherwise removed from) its corresponding IC area of the debonding layer. It will be appreciated that peeling is not the only possible way of removing the IC substrate from the IC area. For example, a conventional pick-up assembly process may be used. Such processes are well known by those skilled in the art. For example, Muehlbauer's™ Merlin™ pick-to-tape may be used to remove the IC substrate from the IC area. This is again another well-known process by those skilled in the art.

Clause 1. A method of processing a carrier for supporting a plurality of integrated circuits, ICs, during fabrication and for aiding release of the ICs following fabrication, the method comprising: providing a carrier for supporting a substrate material during fabrication of the ICs on the substrate material, the carrier having a first surface and a second surface opposite the first surface; forming, on the first surface of the carrier, a layer of release material for receiving the substrate material, and for aiding release of the substrate material following fabrication of the ICs; and patterning the release material formed on the carrier to define a plurality of distinct IC support areas in the release material, each IC support area being arranged to bond to a respective portion of the substrate material for fabrication of a corresponding IC on that portion of substrate material; wherein the layer of release material is configured for allowing at least part of at least one specific wavelength of electromagnetic radiation incident on the release material to act, at an interface between the release material and the substrate material, to reduce a strength of the bond between the release material and the substrate material.

Clause 2. The method of clause 1, wherein the carrier is configured for allowing the at least one specific wavelength of electromagnetic radiation, when incident on the second surface of the carrier, to pass through the carrier, and wherein the layer of release material is configured for absorbing part of the at least one specific wavelength of electromagnetic radiation to produce heat in the layer of release material, and for allowing part of the at least one specific wavelength of electromagnetic radiation to pass through the carrier to reach an interface between the release material and the substrate material to reduce the strength of the bond between the release material and the substrate material.

Clause 3. The method of clause 1 or 2, wherein the patterning of the release material forms a plurality of regions extending between and/or adjacent to the IC support areas, at least part of each region comprising an absence of release material or a thinner layer of release material.

Clause 4. The method of clause 3, wherein at least one region of the plurality of regions comprises release material forming at least one test structure support area, each test structure support area being arranged to bond to a respective further portion of the substrate material for fabrication of a corresponding test structure on that portion of the substrate material.

Clause 5. The method of clause 3 or 4, wherein at least one region of the plurality of regions comprises a linear repeating pattern of windows in the release material that extends generally parallel to an edge of at least one IC support area, each window comprising an absence of release material or a thinner layer of release material.

Clause 6. The method of clause 3 or 4, wherein at least one region of the plurality of regions comprises a portion of release material that connects neighbouring IC support areas.

Clause 7. The method of any preceding clause, wherein the patterning of the release material defines at least one feature pattern in at least one edge of at least one of the IC support areas, the at least one feature pattern comprising an absence of release material or a thinner layer of release material.

Clause 8. The method of any preceding clause, wherein the patterning of the release material forms IC support areas that are configured to act as a photomask during subsequent processing to pattern the substrate material.

Clause 9. The method of any preceding clause, wherein the patterning of the release material comprises: applying a photoresist to the release material; applying electromagnetic radiation to the release material through a photomask for selectively exposing the photoresist to the applied electromagnetic radiation; removing photoresist to define a pattern to be etched in the release material; and etching the release material where the photoresist has been removed.

Clause 10. The method of clause 1 to 8, further comprising: forming a template layer on the first surface of the carrier prior to forming the layer of release material; and patterning the template layer to define a plurality of distinct windows, in the template layer, corresponding to the IC support areas wherein, following the formation of the layer of release material, the release material covers the plurality of distinct windows and remaining part of the template layer.

Clause 11. The method of clause 10, wherein the patterning of the release material comprises: removing the template layer from the first surface to define the plurality of distinct IC support areas in the release material.

Clause 12. The method of any preceding clause, wherein the layer of release material has a thickness of between 20 nm and 300 nm, preferably between 23 nm and 150 nm.

Clause 13. The method of any preceding clause, wherein the release material is formed of one or more metals selected from one or more of groups 4, 5 and 6 of the periodic table.

Clause 14. The method of any preceding clause, wherein the release material is formed of one more metals, oxides of metals, or alloys of metals, wherein said metals are selected from one or more of: Hafnium (Hf), Vanadium (V), Niobium (Nb), Tantalum (Ta), Titanium (Ti), Tungsten (W), Molybdenum (Mo), Aluminium (Al), Copper (Cu), Gold (Au), Silver (Ag), Iron (Fe), Tin (Sn), Zinc (Zn), Cobalt (Co), Chromium (Cr), Germanium (Ge), Palladium (Pd), Platinum (Pt), Rhodium (Rh), Manganese (Mn), Nickel (Ni), Silicon (Si), or Tellurium (Te).

Clause 15. The method of clause 14, wherein the release material is formed of one or more metals, oxides of metals, or alloys of metals, wherein said metals are selected from: Chromium (Cr); Hafnium (Hf), Molybdenum (Mo), Niobium (Nb), Tantalum (Ta), Titanium (Ti), Tungsten (W), or Vanadium (V).

Clause 16. The method of any preceding clause, wherein the carrier is formed of glass, polycarbonate or quartz.

Clause 17. A method of manufacturing at least one IC, the method comprising: providing a carrier processed in accordance with the method of any of clauses 1 to 13; forming a layer of the substrate material on the carrier; patterning the substrate material to form a respective portion of the substrate material on each IC support area; fabricating a respective IC on each portion of the substrate material; irradiating the carrier with the at least one specific wavelength of electromagnetic radiation to reduce the strength of the bond between the release material and the substrate material; and removing at least one portion of the substrate material, on which the at least one IC is fabricated, from the carrier.

Clause 18. The method of clause 17, wherein the patterning of the substrate material comprises: applying a photoresist to the substrate material; applying electromagnetic radiation to the substrate material through a photomask for selectively exposing the photoresist to the applied electromagnetic radiation; removing photoresist to define a pattern to be etched in the substrate material; and etching the substrate material where the photoresist has been removed.

Clause 19. The method of clause 17, wherein the substrate material is photoimageable, and patterning of the substrate material comprises: applying electromagnetic radiation to the substrate material through a photomask for selectively exposing the substrate material to the applied electromagnetic radiation; and etching the substrate material where it was exposed to the applied electromagnetic radiation.

Clause 20. The method of clause 19, wherein the electromagnetic radiation is applied to the substrate through the second surface of the carrier, and wherein the plurality of distinct IC support areas form the photomask.

Clause 21. The method of clause 17, wherein the patterning of the substrate material comprises: applying a photoresist to the substrate material; applying electromagnetic radiation to the second surface of the carrier for selectively exposing the photoresist to the applied electromagnetic radiation through the carrier, the layer of release material acting as a photomask; removing photoresist to define a pattern to be etched in the substrate material; and etching the substrate material where the photoresist has been removed.

Clause 22. The method of clause 17 to 21, wherein the patterning of the release material forms a plurality of regions extending between and/or adjacent to the IC support areas, and the method further comprises forming at least one test structure in at least one region of the plurality of regions.

Clause 23. The method of clause 17 to 22, wherein irradiating the second surface of the carrier comprises irradiating the second surface to induce, through absorption of radiation by the substrate material, photonic ablation at an interface between the release material and the substrate material to reduce the strength of the bond between the release material and the substrate material.

Clause 24. A structure for supporting a plurality of integrated circuits, ICs, during fabrication and for aiding release of the ICs following fabrication, the structure comprising: a carrier for supporting a substrate material during fabrication of the ICs on the substrate material; and a layer of release material formed, on a surface of the carrier, for receiving the substrate material, and for aiding release of the substrate material following fabrication of the ICs; wherein the release material is patterned on the carrier to define a plurality of distinct IC support areas in the release material, each IC support area being arranged to bond to a respective portion of the substrate material for fabrication of a corresponding IC on that portion of substrate material; and wherein the layer of release material is configured for allowing at least part of at least one specific wavelength of electromagnetic radiation incident on the release material to act, at an interface between the release material and the substrate material, to reduce a strength of the bond between the release material and the substrate material.

Clause 25. Apparatus for processing a carrier for supporting a plurality of integrated circuits, ICs, during fabrication and for aiding release of the ICs following fabrication, the apparatus comprising: means for providing a carrier for supporting a substrate material during fabrication of the ICs on the substrate material, the carrier having a first surface and a second surface opposite the first surface; means for forming, on the first surface of the carrier, a layer of release material for receiving the substrate material, and for aiding release of the substrate material following fabrication of the ICs; and means for patterning the release material formed on the carrier to define a plurality of distinct IC support areas in the release material, each IC support area being arranged to bond to a respective portion of the substrate material for fabrication of a corresponding IC on that portion of substrate material; wherein the layer of release material is configured for allowing at least part of at least one specific wavelength of electromagnetic radiation incident on the release material to act, at an interface between the release material and the substrate material, to reduce a strength of the bond between the release material and the substrate material.

Clause 26. Apparatus for manufacturing at least one IC, the apparatus comprising: apparatus according to claim 25 for processing a carrier to form a structure according to claim 24; means for forming a layer of the substrate material on the carrier; means for patterning the substrate material to form a respective portion of the substrate material on each IC support area; means for fabricating a respective IC on each portion of the substrate material; means for irradiating the carrier with the at least one specific wavelength of electromagnetic radiation to reduce the strength of the bond between the release material and the substrate material; and means for removing at least one portion of the substrate material, on which the at least one IC is fabricated, from the carrier.

What is claimed is:

1. A method of processing a carrier for supporting a plurality of integrated circuits, ICs, during fabrication and for aiding release of the ICs following fabrication, the method comprising:
providing a carrier for supporting a substrate material during fabrication of the ICs on the substrate material, the carrier having a first surface and a second surface opposite the first surface;
forming, on the first surface of the carrier, a layer of release material for receiving the substrate material, and for aiding release of the substrate material following fabrication of the ICs; and
patterning the release material formed on the carrier to define a plurality of distinct IC support areas in the release material, each IC support area being arranged to bond to a respective portion of the substrate material for fabrication of a corresponding IC on that portion of substrate material;
wherein the layer of release material is configured for allowing at least part of at least one specific wavelength of electromagnetic radiation incident on the release material to act, at an interface between the release material and the substrate material, to reduce a strength of the bond between the release material and the substrate material.

2. The method of claim 1, wherein the carrier is configured for allowing the at least one specific wavelength of electromagnetic radiation, when incident on the second surface of the carrier, to pass through the carrier, and wherein the layer of release material is configured for absorbing part of the at least one specific wavelength of electromagnetic radiation to produce heat in the layer of release material, and for allowing part of the at least one specific wavelength of electromagnetic radiation to pass through the carrier to reach an interface between the release material and the substrate material to reduce the strength of the bond between the release material and the substrate material.

3. The method of claim 1, wherein the patterning of the release material forms a plurality of regions extending between and/or adjacent to the IC support areas, at least part of each region comprising an absence of release material or a thinner layer of release material.

4. The method of claim 3, wherein at least one region of the plurality of regions comprises release material forming at least one test structure support area, each test structure support area being arranged to bond to a respective further portion of the substrate material for fabrication of a corresponding test structure on that portion of the substrate material.

5. The method of claim 3, wherein at least one region of the plurality of regions comprises a linear repeating pattern of windows in the release material that extends generally parallel to an edge of at least one IC support area, each window comprising an absence of release material or a thinner layer of release material.

6. The method of claim 3, wherein at least one region of the plurality of regions comprises a portion of release material that connects neighbouring IC support areas.

7. The method of claim 1, wherein the patterning of the release material includes at least one of:
defining at least one feature pattern in at least one edge of at least one of the IC support areas, the at least one feature pattern comprising an absence of release material or a thinner layer of release material; or
forming IC support areas that are configured to act as a photomask during subsequent processing to pattern the substrate material.

8. The method of claim 1, wherein the patterning of the release material comprises: applying a photoresist to the release material; applying electromagnetic radiation to the release material through a photomask for selectively exposing the photoresist to the applied electromagnetic radiation; removing photoresist to define a pattern to be etched in the release material; and etching the release material where the photoresist has been removed.

9. The method of claim 1, comprising:
forming a template layer on the first surface of the carrier prior to forming the layer of release material; and
patterning the template layer to define a plurality of distinct windows, in the template layer, corresponding to the IC support areas wherein, following the formation of the layer of release material, the release material covers the plurality of distinct windows and remaining part of the template layer, wherein:
patterning of the release material comprises removing the template layer from the first surface to define the plurality of distinct IC support areas in the release material.

10. The method of claim 1, wherein the layer of release material has a thickness of between 20 nm and 300 nm.

11. The method of claim 1, wherein the release material is formed of:
one or more metals selected from one or more of groups 4, 5 and 6 of the periodic table; or
one or more metals, oxides of metals, or alloys of metals, wherein said metals are selected from one or more of: Hafnium (Hf), Vanadium (V), Niobium (Nb), Tantalum (Ta), Titanium (Ti), Tungsten (W), Molybdenum (Mo), Aluminium (Al), Copper (Cu), Gold (Au), Silver (Ag), Iron (Fe), Tin (Sn), Zinc (Zn), Cobalt (Co), Chromium (Cr), Germanium (Ge), Palladium (Pd), Platinum (Pt), Rhodium (Rh), Manganese (Mn), Nickel (Ni), Silicon (Si), or Tellurium (Te).

12. The method of claim 1, wherein the carrier is formed of glass, polycarbonate or quartz.

13. A method of manufacturing at least one IC, the method comprising: providing a carrier processed by a method comprising:
providing a carrier for supporting a substrate material during fabrication of the ICs on the substrate material, the carrier having a first surface and a second surface opposite the first surface;
forming, on the first surface of the carrier, a layer of release material for receiving the substrate material, and for aiding release of the substrate material following fabrication of the ICs; and
patterning the release material formed on the carrier to define a plurality of distinct IC support areas in the release material, each IC support area being arranged to bond to a respective portion of the substrate material for fabrication of a corresponding IC on that portion of substrate material;
wherein the layer of release material is configured for allowing at least part of at least one specific wavelength of electromagnetic radiation incident on the release material to act, at an interface between the release material and the substrate material, to reduce a strength of the bond between the release material and the substrate material; forming a layer of the substrate material on the carrier; and
patterning the substrate material to form a respective portion of the substrate material on each IC support area; fabricating a respective IC on each portion of the substrate material; irradiating the carrier with the at least one specific wavelength of electromagnetic radiation to reduce the strength of the bond between the release material and the substrate material; and removing at least one portion of the substrate material, on which the at least one IC is fabricated, from the carrier.

14. The method of claim 13, wherein the patterning of the substrate material comprises: applying a photoresist to the substrate material; applying electromagnetic radiation to the substrate material through a photomask for selectively exposing the photoresist to the applied electromagnetic radiation; removing photoresist to define a pattern to be etched in the substrate material; and etching the substrate material where the photoresist has been removed.

15. The method of claim 13, wherein the substrate material is photoimageable, and patterning of the substrate material comprises: applying electromagnetic radiation to the substrate material through a photomask for selectively exposing the substrate material to the applied electromagnetic radiation; and etching the substrate material where it was exposed to the applied electromagnetic radiation.

16. The method of claim 15, wherein the electromagnetic radiation is applied to the substrate through the second surface of the carrier, and wherein the plurality of distinct IC support areas form the photomask.

17. The method of claim 13, wherein the patterning of the substrate material comprises: applying a photoresist to the substrate material; applying electromagnetic radiation to the second surface of the carrier for selectively exposing the photoresist to the applied electromagnetic radiation through the carrier, the layer of release material acting as a photomask; removing photoresist to define a pattern to be etched in the substrate material; and etching the substrate material where the photoresist has been removed.

18. The method of claim 13, wherein the patterning of the release material forms a plurality of regions extending between and/or adjacent to the IC support areas, and the method further comprises forming at least one test structure in at least one region of the plurality of regions.

19. The method of claim 17, wherein irradiating the second surface of the carrier comprises irradiating the second surface to induce, through absorption of radiation by the substrate material, photonic ablation at an interface between the release material and the substrate material to reduce the strength of the bond between the release material and the substrate material.

20. A structure for supporting a plurality of integrated circuits, ICs, during fabrication and for aiding release of the ICs following fabrication, the structure comprising:
a carrier for supporting a substrate material during fabrication of the ICs on the substrate material; and
a layer of release material formed, on a surface of the carrier, for receiving the substrate material, and for aiding release of the substrate material following fabrication of the ICs;
wherein the release material is patterned on the carrier to define a plurality of distinct IC support areas in the release material, each IC support area being arranged to bond to a respective portion of the substrate material for fabrication of a corresponding IC on that portion of substrate material; and
wherein the layer of release material is configured for allowing at least part of at least one specific wavelength of electromagnetic radiation incident on the release material to act, at an interface between the release material and the substrate material, to reduce a strength of the bond between the release material and the substrate material.
